(19) United States
(12) Patent Application Publication
(10) Pub. No.: US 2009/0253051 A1
(43) Pub. Date: Oct. 8, 2009

(54) PHASE SHIFT MASK AND METHOD OF FABRICATING THE SAME

(75) Inventor: Dae Woo KIM, Yongin-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,692

(22) Filed: Jun. 27, 2008

(30) Foreign Application Priority Data
Apr. 3, 2008 (KR) 2008-31151

(51) Int. Cl. G03F 1/00

(52) U.S. Cl. 430/5

(57) ABSTRACT

The present invention relates to a phase shift mask and a method of fabricating the same. According to an aspect of the present invention, a method of fabricating a phase shift mask includes forming a phase shift layer and a light-shielding layer over a transparent substrate including a cell area and a frame area, patterning the light-shielding layer to thereby form light-shielding layer patterns, patterning the phase shift layer in a width narrower than that of the light-shielding layer pattern by performing an etch process using the light-shielding layer patterns as a mask, and removing the light-shielding layer patterns of the cell area.

### CROSS-REFERENCES TO RELATED APPLICATION

The present application claims priority to Korean patent application number 10-2008-0031151, filed on Apr. 3, 2008, which is incorporated by reference in its entirety.

### BACKGROUND OF THE INVENTION

The present invention relates to a phase shift mask and, more particularly, to a method of fabricating a phase shift mask, which can correct the line width by performing sidewall etching of a phase shift layer, which is patterned by an etch process using light-shielding layer patterns as a mask.

In fabricating semiconductor devices, two important processes for increasing the level of integration are photolithography and etching processes. In the fabrication process, after the semiconductor layers are formed, the photoresist material is coated on the layers. In this state, if light is exposed using an optical mask having desired patterns formed therein, the light passing through the optical mask is transferred to a photoresist film. The desired patterns are formed by performing a development process. If a dry etch process is performed using the formed photoresist film patterns as a mask, patterns are formed in the underlying semiconductor layers.

Recently, as the level of integration is accelerated and therefore the size of a unit element decreases, a line width is narrowed. Thus, a patterning limit has been reached in which patterns of a specific width or less cannot be formed. This is due to the diffraction of light passing through a mask, in which micro patterns are formed, and an interference phenomenon. In order to overcome this patterning limit, a phase shift mask has been introduced which can increase the resolution of a pattern and realize a micro line width using a phase shift material for forming micro patterns. In the fabrication process of the phase shift mask for forming micro patterns of a semiconductor device, accuracy and uniformity of a smaller line width becomes important. It has become necessary to control the line width using smaller critical dimensions.

Generally, during the process, there are factors which affect line width error. An E-beam exposure apparatus generates a fogging effect and a proximity effect due to a pattern density and a high acceleration voltage, causing error in the pattern density and the line width region. In development and etch processes, it is not easy to control the line width accurately because of a loading effect. Therefore, as a control method for obtaining a conventional micro line width, it is necessary to use an E-beam exposure apparatus and a photoresist material with excellent energy margin; reduce the loss of a photoresist material at an unexposed portion by securing the contrast between the unexposed portion and an exposed portion in a development process; and introduce an apparatus and process conditions for reducing the loading effect depending on the selectivity of an etch process and a pattern density. This is because the line width of a typical phase shift mask is controlled by the energy of an exposure apparatus, and development and etch processes.

In order to correct line width error, fogging effect correction (FEC), proximity effect correction (PEC), etc. of an E-beam exposure apparatus are used. However, the methods have limitations with line width error because of more complicated patterns and an increased pattern density. In particular, when the line width of a formed pattern is inaccurate, a new mask must be fabricated since a rework is impossible. In this case, problems arise because the fabrication time is greatly increased and the fabrication cost is increased due to a long exposure time of an E-beam exposure apparatus.

To solve the above problems, a method employing partial etching of a light-shielding layer has been used as one method for controlling the accuracy of a micro line width in the existing apparatus and process conditions. According to this method, after a secondary exposure process is in a state where a light-shielding layer is patterned, a light-shielding layer pattern is etched additionally until a desired line width is obtained. A phase shift layer is etched using the light-shielding layer patterns with a reduced line width as a mask. In order to remove the light-shielding layer remaining on the phase shift layer pattern, a third exposure process is performed to thereby obtain a phase shift mask with a corrected line width.

However, in the above method, when a high light-shielding layer is etched additionally, the accuracy of line width correction is lowered due to the loading effect. Thus, in order to prevent this problem, a photoresist material is coated, an exposure process is performed and the light-shielding layer is then etched. Accordingly, one more exposure process is necessary when compared with a typical fabrication process of a phase shift mask, and removal and cleaning processes of a photoresist film are also required. Consequently, this method has a high defect occurrence probability due to increased process steps.

### BRIEF SUMMARY OF THE INVENTION

The present invention relates to a phase shift mask and a method of fabricating the same, in which sidewall etching is performed on a patterned phase shift layer by performing an etch process using light-shielding layer patterns as a mask, while pattering the phase shift layer, in order to correct the line width of the phase shift layer pattern, so that the loading effect depending on the pattern density can be reduced and the accuracy of a micro line width can be controlled simply using existing exposure and process apparatuses, and the process can be simplified.

A method of fabricating a phase shift mask in accordance with an aspect of the present invention includes forming a phase shift layer and a light-shielding layer over a transparent substrate including a cell area and a frame area, patterning the light-shielding layer to thereby form light-shielding layer patterns, patterning the phase shift layer in a width narrower than that of the light-shielding layer pattern by performing an etch process using the light-shielding layer patterns as a mask, and removing the light-shielding layer patterns of the cell area.

The phase shift layer can be formed of MoSiN or MoSiON. The light-shielding layer can be formed of chrome (Cr).

The phase shift layer can be patterned by an etch process employing a dry etchback or wet etchback process. The etch process can be performed under condition that an etch rate of the phase shift layer and the transparent substrate ranges from 5:1 to 10:1.

The etch process can use either chlorine or a compound, including chlorine atoms, as a main etch gas. The etch process can be performed using the main etch gas, which includes at least one of a gas including hydrogen, a gas including fluorine, and an inert gas, as an addition etch gas.

When the phase shift layer is patterned, sidewalls of the patterned phase shift layer can be etched. After the phase shift layer is patterned by the sidewall etch of the phase shift layer, phase shift layer patterns can be formed to have a target line width.

When the phase shift layer is patterned, the phase shift layer can be over etched.

A phase shift mask in accordance with another aspect of the present invention includes a transparent substrate including a cell area and a frame area, phase shift layer patterns formed over the transparent substrate of the cell area and the frame area, and a light-shielding layer pattern formed on the phase shift layer pattern in the frame area.

A phase shift mask in accordance with still another aspect of the present invention includes a transparent substrate, including a first area and a second area in which more dense patterns than those of the first area are formed, phase shift layer patterns formed over the transparent substrate of the first area and the second area, and a light-shielding layer pattern formed on the phase shift layer pattern in the first area.

### BRIEF DESCRIPTION OF THE DRAWINGS

FIGS. 1A to 1F are sectional views illustrating a method of fabricating a phase shift mask in accordance with an embodiment of the present invention;

FIG. 2 is a layout diagram showing a phase shift mask formed in accordance with an embodiment of the present invention; and

FIG. 3 is a layout diagram showing a phase shift mask formed in accordance with another embodiment of the present invention.

### DESCRIPTION OF SPECIFIC EMBODIMENTS

Specific embodiments according to the present invention will be described with reference to the accompanying drawings. However, the present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

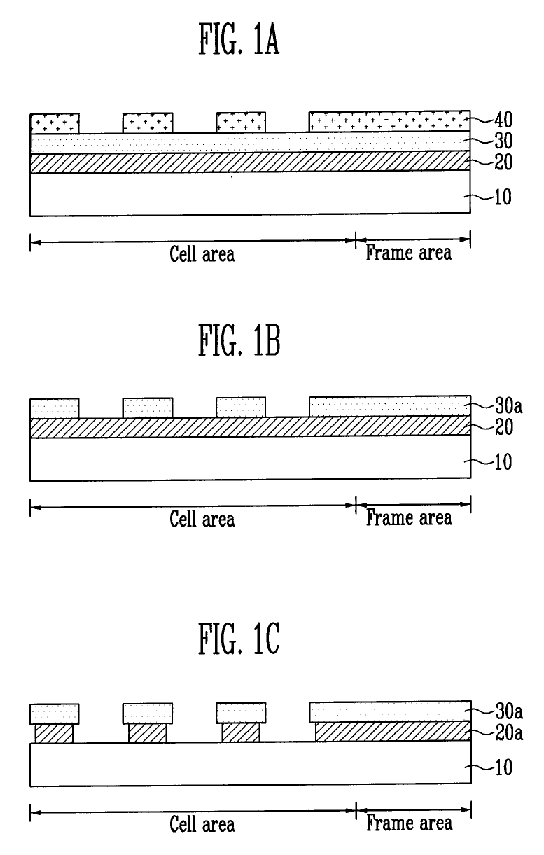

FIGS. 1A to 1F are sectional views illustrating a method of fabricating a phase shift mask in accordance with an embodiment of the present invention. Referring to FIG. 1A, a transparent substrate 10 is provided. The substrate 10 includes a cell area, and a frame area in which an alignment key, an alignment mark, etc., which are necessary for an exposure process, are mounted. Here, it is assumed that the frame area is an area in which more dense patterns are formed when compared with the cell area. The transparent substrate 10 can be formed from a transparent material such as quartz.

A phase shift layer 20 and a light-shielding layer 30 are sequentially stacked over the transparent substrate 10. The phase shift layer 20 shifts the passing light by 180 degrees in order to increase the resolution. The phase shift layer 20 can be formed from material with a transmittance of about 6 to 8%, for example, MoSiN or MoSiON. The light-shielding layer 30 can be formed from material with a transmittance of about 0 to 5%, for example, chrome (Cr).

First photoresist film patterns 40 to be used as a mask are formed on the light-shielding layer 30. The first photoresist film patterns 40 can be formed by coating a chemically amplified positive photoresist on the light-shielding layer 30 using a spin coating method and then performing exposure and development processes employing a pre-designed mask (not shown). Here, an exposure apparatus can employ an existing E-beam exposure apparatus.

In general, exposed portions of a positive photoresist are selectively removed using a developer. Thus, a plurality of the first photoresist film patterns 40, which are spaced apart from each other at specific intervals, is formed in the cell area. An integral first photoresist film pattern 40 is formed in the frame area. That is, patterning is not performed in the frame area.

However, typically, the first photoresist film patterns 40 formed using an existing exposure apparatus may have a line width error due to the fogging effect, the proximity effect, etc., which is caused by the E-beam exposure apparatus. Here, line width error indicates error with respect to an average value of a target line width of the first photoresist film patterns 40. Thus, the first photoresist film patterns 40 are formed to have a larger width than a target line width of a phase shift layer pattern (to be formed in a subsequent process) due to such line width error.

Referring to FIG. 1B, the light-shielding layer 30 is patterned by performing an etch process using the first photoresist film patterns (refer to 40 of FIG. 1A) as a mask. Consequently, light-shielding layer patterns 30a, having a larger line width than a target line width of a phase shift layer pattern (to be formed in a subsequent process) are formed on the phase shift layer 20. The first photoresist film patterns (refer to 30 of FIG. 1A) are then removed.

Referring to FIG. 1C, the phase shift layer (refer to 20 of FIG. 1B) is patterned in such a way as to have a narrower width than that of the light-shielding layer patterns 30a by performing an etch process using the light-shielding layer patterns 30a as a mask. To this end, the etch process is performed (using the light-shielding layer patterns 30a as a mask) simultaneously with the sidewall etching of the phase shift layer patterns. This allows the line width of the phase shift layer pattern 20a to be corrected while pattering the phase shift layer (refer to 20 of FIG. 1B). This is because, if the underlying phase shift layer (refer to 20 of FIG. 1B) is patterned using the light-shielding layer patterns 30a having a line width error as a mask, a desired width of a phase shift layer pattern 20a cannot be obtained.

Here, the etch process can be performed using a dry or wet etchback process. The dry etchback process having an anisotropic etch characteristic may be used rather than a wet etchback process having an isotropic etch characteristic in order to control a micro line width.

The etch process can be performed using an etch recipe having a high etch rate with respect to the phase shift layer (refer to 20 of FIG. 1B) rather than the light-shielding layer patterns 30a and the transparent substrate 10. The etch process can be performed under a condition that the etch rate of the phase shift layer (refer to 20 of FIG. 1B) to the transparent substrate 10 ranges from 5:1 to 10:1 while not etching the light-shielding layer patterns 30a. To this end, when the phase shift layer (refer to 20 of FIG. 1B) is etched, chlorine, or a compound including chlorine atoms, such as Cl₂ and BCl₃ can be used as a main etch gas.

Further, the main etch gas may include an inert gas, such as N₂, Ar or H₂, as an additional etch gas. This gas functions to carry a reaction gas, which directly participates in a reaction in the etch reaction gas, and forms an atmosphere within a reaction chamber. The main etch gas may further include a gas, including hydrogen (H), as an additional etch gas. This gas functions to prevent an arcing phenomenon from occurring upon etching. The main etch gas may further include a gas, including fluorine (F) such as CF₄, SF₆ or C₂F₆, as an additional etch gas. This gas functions to increase the etch rate of the phase shift layer (refer to 20 of FIG. 1B) and thus improve the etch rate with respect to the phase shift layer (refer to 20 of FIG. 1B).

Accordingly, the phase shift layer patterns 20a having a width narrower than that of the light-shielding layer patterns 30a are formed. Here, the phase shift layer patterns 20a have a corrected line width, resulting in a targeted line width.

In general, a skew or etch bias of the phase shift layer with respect to the light-shielding layer is almost identical. Thus, the line width of the phase shift layer pattern can be predicted on the basis of the line width of the light-shielding layer pattern. Therefore, a skew of a designed line width and a line width between target patterns can be controlled to become almost 0. This is done by simply controlling the degree of correction of the line width by improving the sidewall etching performance of the phase shift layer (refer to 20 of FIG. 1B) through control of etch conditions, including an etch rate, an etch gas, an etch amount, an etch time, etc. Thus, the phase shift layer patterns 20a are accurately controlled to have a desired line width.

In particular, if the sidewall etching is performed while patterning the phase shift layer (refer to 20 of FIG. 1B) using a high etch rate with respect to the phase shift layer (refer to 20 of FIG. 1B) rather than the light-shielding layer patterns 30a, the etch rate of the phase shift layer (refer to 20 of FIG. 1B) becomes fast and an etch time is shortened. Accordingly, the loading effect dependent on a pattern density can be reduced. Thus, exposure and development processes can be reduced when compared with a conventional method.

Further, although photoresist film patterns formed with an incorrect line width using the existing exposure and process apparatus is employed, a desired line width can be realized by performing an etch process on the phase shift layer (refer to 20 of FIG. 1B). Thus, additional cost or mask loss can be reduced.

Meanwhile, when patterning the phase shift layer (refer to 20 of FIG. 1B), some over etch with respect to the phase shift layer (refer to 20 of FIG. 1B) is possible. A phase change due to such over etch can be corrected by controlling the thickness of the phase shift layer patterns 20a through a cleaning process of the phase shift mask.

Referring to FIG. 1D, a photoresist film 50 is formed over the transparent substrate 10, including the phase shift layer patterns 20a with a corrected line width and the light-shielding layer patterns 30a. The photoresist film 50 can be formed by coating a chemical amplification positive photoresist using a spin coating method.

Thereafter, the photoresist film 50 of the cell area is selectively exposed. The exposure process can be performed using a laser beam exposure apparatus and may employ blanket exposure, if appropriate.

Referring to FIG. 1E, the exposed photoresist film (refer to 50 of FIG. 1D) is developed. Consequently, the exposed photoresist film (refer to 50 of FIG. 1D) of the cell area is removed by a developer, so that a second photoresist film pattern 50a remains only on the light-shielding layer pattern 30a of the frame area.

Referring to FIG. 1F, the exposed light-shielding layer patterns (refer to 30a of FIG. 1E) are removed by an etch process using the second photoresist film pattern (refer to 50a of FIG. 1E) as a mask. Therefore, the light-shielding layer patterns (refer to 30a of FIG. 1E) of the cell area are all removed, so only the phase shift layer pattern 20a remains on the transparent substrate 10.

Next, the second photoresist film pattern (refer to 50a of FIG. 1E) is removed. Consequently, a stack layer of the phase shift layer pattern 20a and the light-shielding layer pattern 30a remains in the frame area of the transparent substrate 10. As described above, the light-shielding layer pattern 30a remains in the frame area such that light, which is necessary for alignment and measurement, transmits a reticle and therefore causes problems in recognizing and measuring an alignment key pattern. The size of the phase shift layer pattern 20a which is opened (depending on whether the pattern of a frame edge area exists or not), may be varied, and can be opened typically in the range of 200 to 500 nm.

Through this method, a phase shift mask 60 is completed. Where the phase shift layer patterns 20a, having a corrected and target line width, are formed in the cell area of the transparent substrate 10 and the stack layer of the phase shift layer pattern 20a and the light-shielding layer pattern 30a is formed in the frame area of the transparent substrate 10. Accordingly, the phase shift mask 60 is comprised of a phase shift area B in which about 6 to 8% of light is transmitted through the phase shift layer patterns 20a, a transmit area C through which 100% of light is transmitted, and a light-shielding area D through which about 0 to 5% of light is transmitted.

As described above, according to an embodiment of the present invention, the phase shift mask 60 having the phase shift layer patterns 20a of a target line width can be fabricated by correcting the line width simply through two exposure processes in the same manner as a typical phase shift mask fabrication process. Accordingly, the process can be simplified while increasing the accuracy of line width correction, so a defect occurrence probability can be lowered.

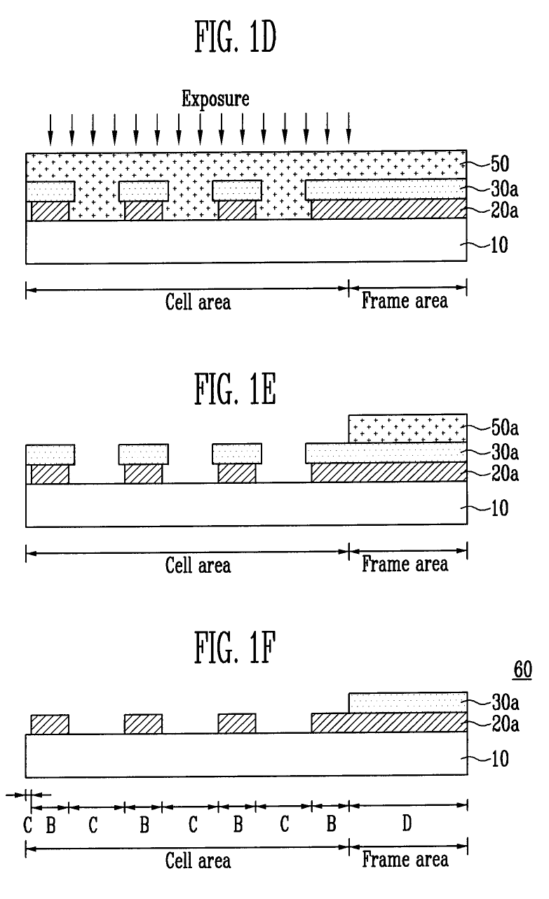

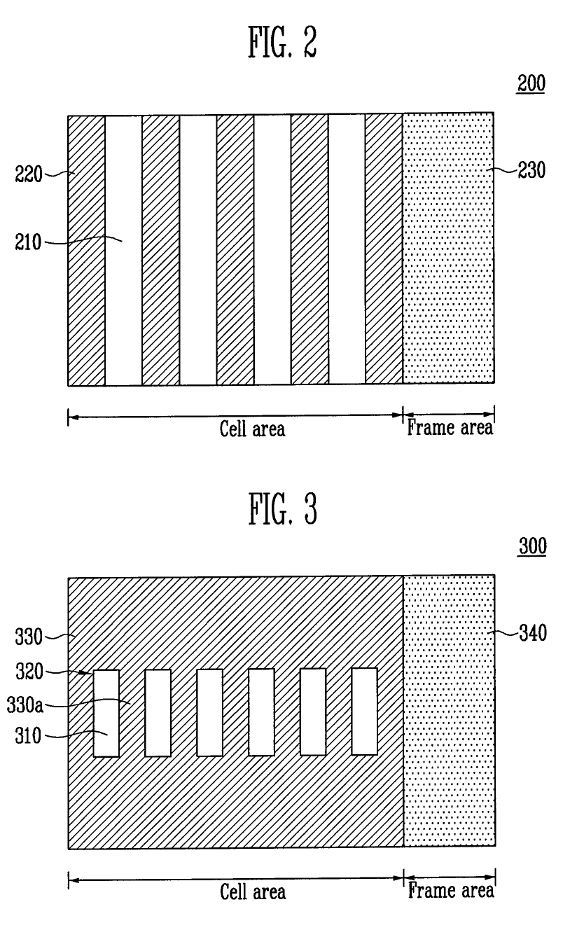

FIG. 2 is a layout diagram showing a phase shift mask formed in accordance with an embodiment of the present invention. FIG. 3 is a layout diagram showing a phase shift mask formed in accordance with another embodiment of the present invention.

Referring to FIG. 2, a phase shift mask 200 can be fabricated using the method described above with reference to FIGS. 1A to 1F. Where phase shift layer patterns 220 of a line pattern (in which bit lines, word lines, etc. can be formed) are formed in a cell area on a transparent substrate 210, and a stack layer of the phase shift layer pattern 220 and a light-shielding layer pattern 230 is formed in a frame area on the transparent substrate. Here, the phase shift layer pattern 220 is formed to have a target line width through line width correction.

Referring to FIG. 3, a phase shift mask 300 can be fabricated using the method described above with reference to FIGS. 1A to 1F. Where a phase shift layer pattern 330 (including contact holes 320) can be formed in a cell area on a transparent substrate 310 and a stack layer of the phase shift layer pattern and a light-shielding layer pattern 340 is formed in a frame area on the transparent substrate. Here, line patterns 330a located between the contact holes 320, in the phase shift layer pattern 330, can be formed to have a target line width through line width correction.

As described above, the present invention can have the following advantages. First, sidewalls of a patterned phase shift layer are etched by an etch process using light-shielding layer patterns as a mask while pattering the phase shift layer. Here, the phase shift layer pattern is corrected to have a desired line width by simply controlling etch conditions. Accordingly, a skew of a designed line width and a target pattern line width can be controlled to become almost 0.

Second, the loading effect dependent on a pattern density can be reduced by shortening the etch time of a phase shift layer by employing a high etch rate with respect to the phase shift layer rather than a light-shielding layer. Accordingly, a mask having a correct line width can be fabricated using only two exposure processes in the same manner as a typical phase shift mask fabrication process.

Third, although an exposed mask having an incorrect line width is employed, the mask can have a desired line width by performing an etch process for a phase shift layer. Accordingly, additional expenses or mask loss can be reduced.

Fourth, the process can be simplified while increasing the accuracy of line width correction. Thus, a defect occurrence probability can be lowered.

The embodiments disclosed herein have been proposed to allow a person skilled in the art to easily implement the present invention, and the person skilled in the part may implement the present invention by a combination of these embodiments. Therefore, the scope of the present invention is not limited by or to the embodiments as described above, and should be construed to be defined only by the appended claims and their equivalents.

What is claimed is:

1. A method of fabricating a phase shift mask, comprising:
providing a transparent substrate defining a cell area and a frame area;
forming a phase shift layer over the cell area and the frame area of the transparent substrate;
forming a light shielding layer over the phase shift layer, the light shielding layer being over the cell area and the frame area;
patterning the light-shielding layer to form light-shielding layer patterns over the cell area and the frame area;
patterning the phase shift layer using the light-shielding layer patterns as a mask to form phase shift patterns, the phase shift patterns having a smaller width than that of the light-shielding layer; and
removing the light-shielding layer patterns provided in the cell area.

2. The method of claim 1, wherein the phase shift layer includes MoSiN or MoSiON, or both.

3. The method of claim 1, wherein the light-shielding layer includes chrome (Cr).

4. The method of claim 1, wherein the phase shift layer is patterned by an etch process employing a dry etchback or wet etchback process, or both.

5. The method of claim 4, wherein the etch process is performed under condition that an etch rate of the phase shift layer and the transparent substrate ranges from 5:1 to 10:1.

6. The method of claim 4, wherein the etch process uses either chlorine or a compound, including chlorine atoms, as a main etch gas.

7. The method of claim 6, wherein the etch process is performed using the main etch gas, which includes at least one of a gas including hydrogen, a gas including fluorine, and an inert gas, as an addition etch gas.

8. The method of claim 1, wherein when the phase shift layer is patterned, sidewalls of the patterned phase shift layer are etched.

9. The method of claim 8, wherein after the phase shift layer is patterned by the sidewall etch of the phase shift layer, wherein the phase shift layer patterns are formed to have a target line width.

10. The method of claim 8, wherein when the phase shift layer is patterned, the phase shift layer is over etched.

11. A phase shift mask, comprising:
a transparent substrate including a cell area and a frame area;
phase shift layer patterns formed over the transparent substrate of the cell area and the frame area; and
a light-shielding layer pattern formed on the phase shift layer pattern in the frame area.

12. A phase shift mask, comprising:
a transparent substrate including a first area and a second area in which more dense patterns than those of the first area are formed;
phase shift layer patterns formed over the transparent substrate in the first area and the second area; and
a light-shielding layer pattern formed on the phase shift layer pattern in the first area.
